(19) United States
(12) Patent Application Publication
(10) Pub. No.: US 2025/0337224 A1
(43) Pub. Date: Oct. 30, 2025

(54) ELECTRONIC DEVICE WITH AN EMBEDDED HFAC POWER DISTRIBUTION BUS

(71) Applicant: Energy Research Lab Ltd, London (GB)

(72) Inventor: Lee Harrison, London (GB)

(73) Assignee: Energy Research Lab Ltd, London (GB)

(21) Appl. No.: 18/860,786

(22) PCT Filed: Apr. 28, 2023
(86) PCT No.: PCT/GB2023/051141

§ 371 Date: Oct. 28, 2024

(30) Foreign Application Priority Data
Apr. 28, 2022 (GB) 2206237.6

(51) Int. Cl. H02B 1/20

(52) U.S. Cl. CPC H02B 1/20

(57) ABSTRACT

An aspect of the disclosure provides an electronic device comprising: a first substrate comprising a first ground plane and a second ground plane, wherein the first ground plane and the second ground plane are arranged to provide a shielded volume there between. The electronic device also comprises a first high frequency alternating current (HFAC) power distribution bus disposed in the shielded volume, wherein the first HFAC power distribution bus is configured for connecting to a first HFAC power supply. A first power supply connection for connecting the first HFAC power supply to the first HFAC power distribution bus and a component connection for connecting the first HFAC power distribution bus to electronic components carried by the first substrate are also provided.

### FIELD OF INVENTION

The present invention relates to High Frequency Alternating Current, HFAC, devices, in particular, an HFAC power distribution bus embedded in a substrate of an electronic device.

### BACKGROUND

Conventional electrical mains distribution systems and the grid as we know it usually supply electricity at 90-264V AC and the frequency 47-63 Hz, depending on the jurisdiction.

Electrical products are either hard wired with connectors or junction boxes using a variety of mains power connection plugs and sockets or other permanently fixed connection systems. For example, typical servers (e.g. at datacentres) comprise a 12 V DC bus or a 48 V DC bus. Taking these typical DC buses convert the mains AC to a 12 V DC power supply which is routed around a server. DC buses in typical electronic devices (e.g. in servers) have reached the peak of their efficiency capabilities and as they are responsible for a substantial proportion of energy losses in these devices applying HFAC power distribution can provide substantial efficiency gains for the next generation of devices.

In brief, one of the main costs of running a datacentre is the cost of power. A disadvantage of the typical 12 V or 48 V DC buses is that they waste power due to the low voltage DC distribution and subsequent I²R losses. The wasted power is financially disadvantageous.

Furthermore, wasting power conversion from AC to DC can have a negative environmental impact in that more fossil fuels may be required to generate the requisite input power in comparison to if the efficiency of said buses were higher. Social media caused a large increase in data centre traffic coupled with the growth of IOT devices. It is set to grow further with the advent of digital currency, digital ID and digital currency mining.

In more detail typical server power architecture consists of a single or dual N+1 redundant AC power supply that contains a rectifier to convert low frequency DC to DC, followed by power factor correction (PFC) circuit providing a regulated DC bus of 380-400 VDC. This is then stepped down by an additional switching converter and rectified again to produce 12V and 3.3V outputs, in some cases additional converters may be employed to provide additional output voltages. Two identical power supplies are generally fitted with a current share bus implemented to enable sharing of the output rails to provide the N+1 redundancy should one of the power supplies fail. In general, the 12V and 3.3V DC output rails are distributed around a motherboard to point of load or embedded converters that further convert the 12V and 3.3V to supply the correct voltages required for cooling fans, disk drives, network controllers, PCIe expansion, USB and other ancillary circuitry. Higher power DC to DC converters supply power to DDR Memory and CPU power as low as 0.8V at high current.

As described briefly above, power distribution in servers has for many years been of a 12V distributed architecture around the 12V bus, although recent advances have projected this to an increased 48V bus in order to reduce I²R losses and improve efficiency. Drawbacks of any AC DC distribution system are that they impose dual stage power conversion circuits, adding cost, complexity and reducing efficiency. Today's computer systems require high current slew rates, fast rapid changes in current demand, which is challenging for theses common DC distribution architectures. The DC distribution architecture is static, the 12V output for example remains at 12V for any load condition.

Designers seeking to improve the service offered by a particular electronic system in the face of failures in component parts often adopt the “N+1” approach. This technique assumes that “N” number of identical modules are required to achieve the required system performance and an additional unit is supplied to take over the duty of a faulty module. The task of the maintenance staff is to change out the faulty module before another module fails. Implicit in this approach is the assumption that a failure of one unit isolates it from the system in question and that its failure does not provoke failures in its co-functional modules. This approach is used in servers today, implemented in what are commonly referred to as the Front-End Power Supplies.

The system designer needs to avoid the creation of single point failure modes such as at the point of common connection or supply, or if they are unavoidable the reliability of such single point failure nodes should be very high. Techniques have evolved to permit line-replacement of faulty modules without system interruption. This general method has become known as “Plug-and-Play” after the Windows 95 introduction of that feature. Units can operate in parallel, sharing the load, or the extra unit can be forced into a standby state. The standby states can be subdivided into “hot standby” where the unit is powered up but is quiescent, or “cold-standby” where the unit is commanded, somehow, to be OFF, waiting for an activation command. The use of Line Replaceable Units (LRU) with autonomous built-in test equipment (BITE) ensures that the replacement of a unit signaling it is faulty clears the fault indication, whether it is a failure in the main service or in the BITE.

Servers today make use of two identical AC DC Front End power supplies operating in an N+1 redundant mode of operation, allowing the replacement of a failed PSU without shutting down a system. The redundancy in traditional servers does not reach further than the front-end power supplies, any failure of a point of load converter, or embedded DC-DC converter on the motherboard will render the server as failed and not in service.

U.S. Pat. No. 6,593,668 describes a method and apparatus for distributing power in an electronic system including receiving a source power at a system power supply, converting the source power to a plurality of alternating current (AC) signals at multiple frequencies, and transmitting the plurality of AC signals at multiple frequencies to multiple voltage regulator modules (VRMs) in the electronic system. The inventors of the present application have realised a system operating with a HFAC distributed bus at multiple frequencies makes electromagnetic compatibility (EMC) compliance unpredictable, overly complicated and difficult to control. Furthermore, the method described provides no allowance to accommodate redundancy in the front-end power supplies, a general requirement for server power architecture but difficult to achieve with AC power distribution within a server whereby system operation cannot be interrupted on failure or replacement of a power supply in the N+1 configuration.

### SUMMARY

Aspects of the invention are set out in the independent claims and optional features are set out in the dependent claims. Aspects of the disclosure may be provided in conjunction with each other, and features of one aspect may be applied to other aspects.

The present disclosure seeks to provide a means of increasing the efficiency of servers and computers by implementing a distributed HFAC bus which may operate with fixed frequency. The bus may be constant voltage and limited current. In some embodiments the HFAC bus voltage can be adjusted in response to load. Some embodiments make use of redundancy in HFAC power supply, such as N+1 redundancy, and dynamic arbitration between power supplies. Some embodiments use master-slave arbitration to provide synchronous HFAC power from redundant supplies. Some embodiments use multiple HFAC distributed outputs from each HFAC Front-End Power Supply.

Embodiments may make use of a combination of HFAC digitally controlled power, machine learning, GAN and SIC devices. Embodiments may provide a server architecture based upon HFAC power distribution that demonstrates higher efficiency and increased reliability.

The present disclosure provides an electronic device with an embedded HFAC power distribution bus. The electronic device can be deployed in computing systems, for example in servers (e.g., the electronic device may comprise a motherboard of a server). The electronic device is configured to use an HFAC power supply with constant frequency and constant voltage (e.g., selected from the ranges 1 MHZ to 2 MHz and 25 V to 45 V respectively). Advantageously, said HFAC power supplies have a greater efficiency than a typical AC to DC power supply which delivers the same power. As such one or more of the disadvantages described above may be addressed by embodiments of the present disclosure. HFAC power supplies described herein may have a frequency of at least 900 KHz.

The present disclosure also provides an electronic device with two embedded HFAC power distribution buses wherein each of the buses is connected to a respective HFAC power supply. Electronic components can be mounted to the electronic device such that the components can draw power from both of the embedded HFAC power distribution buses. These electronic devices provide N+1 redundancy to said electronic components. As such, electronic device described herein may permit hot swapping of the HFAC power supplies and, therefore, such electronic devices can be deployed in computing systems, for example in servers (e.g. the electronic device may comprise a motherboard of a server).

An aspect of the disclosure provides an electronic device comprising: a first substrate comprising a first ground plane and a second ground plane, wherein the first ground plane and the second ground plane are arranged to provide a shielded volume therebetween; a first high frequency alternating current (HFAC) power distribution bus disposed in the shielded volume, wherein the first HFAC power distribution bus is configured for connecting to a first HFAC power supply; a first power supply connection for connecting the first HFAC power supply to the first HFAC power distribution bus; a component connection for connecting the first HFAC power distribution bus to electronic components carried by the first substrate.

The electronic device is provided with an integral first HFAC power distribution bus disposed in a shielded volume. The electronic device is configured such that radiated or conducted noise generated by the first HFAC power distribution bus in use (i.e. when the first HFAC power distribution bus receives HFAC power from the first power supply connection) is contained by the first and second ground planes. The ground planes need not actually be grounded or connected to a reference voltage and may be floating.

Advantageously, an electronic device is provided whereby electronic components are carried on a substrate and receive power from the first HFAC power distribution bus and the electronic components receive input and output electrical signals which are distinguishable from electrical noise generated by of the HFAC power distribution bus in use.

The HFAC power distribution buses described and claimed herein may each comprise a pair of electrical conduction paths from a power supply connection to component connections. The pair of electrical conduction paths may be matched to provide two conduction paths of equal path length from the HFAC power supply connection to each component connection. In other words, the two paths may be configured so that the signal on each conduction path remains in the same phase relationship with that on the other conduction path at the power supply as at the point electrical power is taken from the bus, e.g. at a connection to a component. The path length may comprise the path length from the power supply connection to an input connection of a rectifier for powering the component. The two conduction paths may be aligned with each other. For example wherein they comprise elongate conductive members disposed parallel to each other. Aligning the electrical conduction paths may reduce an effective H-field generated around said conduction paths when current (e.g. HFAC) flows through said conduction paths in use.

The electronic device may comprise an HFAC power supply connected to the power supply connection. In use, the H-field generated by the first HFAC power distribution bus is reduced by the pair of electrical conduction paths being aligned with each other.

The pair of electrical conduction paths may be separated by part of the first substrate.

At least one of the pair of ground planes may be connected to a reference voltage such as ground. For example wherein one of the pair is a neutral conduction path and the other of the pair is a live conduction path.

The electronic device may comprise a plurality of first conductive spurs connected between the first HFAC power distribution bus and corresponding ones of a plurality of component connections. In examples, said conductive spurs comprise a pair of conductive traces.

The component connections may be provided by vias through the first ground plane or the second ground plane. The vias may be full vias through each PCB layer or consist of blind vias to reduce generated noise on the PCB.

In examples, at least one of the component connections connects the first HFAC power distribution bus to an electronic component disposed outside of the shielded volume. For example, a HFAC-DC converter may be disposed between the HFAC power distribution bus and the component disposed outside of the shielded volume.

The electronic device may comprise a second power supply connection for connecting an HFAC power supply to the HFAC power distribution bus.

The electronic device may comprise a synchronisation connection for connecting HFAC power supplies connected to the power supply connections to enable the HFAC power supplies to synchronise with each other. The power supply may have a constant voltage amplitude and the two supplies may be synchronised so that the voltages are in phase and of the same (constant) frequency.

The electronic device may comprise a second HFAC power distribution bus disposed in the shielded volume. In examples, the second HFAC power distribution bus is configured for connecting to the second HFAC power supply. In examples, the first HFAC power distribution bus and the second HFAC power distribution bus is connected to the component connection. Advantageously, N+1 redundancy may be provided to a component connected to both the first HFAC power distribution bus and the second HFAC power distribution bus.

The electronic device may comprise two rectifiers for providing DC power to the component connection, wherein the first HFAC power distribution bus is connected to a first of the two rectifiers and the second HFAC power distribution bus is connected to a second of the two rectifiers.

The electronic device may comprise two DC-DC converters wherein each rectifier is connected to the component connection by a corresponding one of the two DC-DC converters.

In examples, the electronic device may comprise one DC-DC converter wherein both rectifiers are connected to the component connection by the DC-DC converter.

In examples, the electronic device may comprise a wired connection for connecting the first HFAC power distribution bus to a second substrate separate from the first substrate. The electronic device may comprise the second substrate, wherein the wired connection connects to a third HFAC power distribution bus in the second substrate.

An aspect of the disclosure is a server comprising a first HFAC power supply and a motherboard, wherein the motherboard comprises a first substrate comprising a first ground plane and a second ground plane, wherein the first ground plane and the second ground plane are arranged to provide a shielded volume therebetween; a first high frequency alternating current (HFAC) power distribution bus disposed in the shielded volume, wherein the first HFAC power distribution bus is configured for connecting to the first HFAC power supply; a first power supply connection for connecting the first HFAC power supply to the HFAC power distribution bus; a component connection for connecting the first HFAC power distribution bus to electronic components carried by the first substrate.

An aspect of the disclosure provides an electronic device comprising: a first HFAC power distribution bus, a first HFAC power supply connected to the first HFAC power distribution bus; a second HFAC power distribution bus, a second HFAC power supply connected to the second HFAC power distribution bus; at least one component connection for connecting an electronic component to be powered to the first HFAC power distribution bus and/or the second HFAC power distribution bus. The first HFAC power distribution bus and the second HFAC distribution bus may be arranged so that they provide power supply signals which are in phase at connection to the components which are to be powered. For example, the path length of the two buses may be matched from the two supplies to each component.

The component connection may comprise conductive material for physically connecting the components to either or both of the HFAC buses. This may provide ohmic (and optionally capacitive) coupling of the components to the buses.

Advantageously, the electronic device provides an electronic component with N+1 redundancy. In particular, the electronic component is configured to receive power from both a first HFAC power distribution bus and the second HFAC power distribution bus. For example, the electronic component is configured to receive power from the first HFAC power distribution bus and, in the event there is an interruption in the power from the first HFAC power distribution bus, then the electronic component is configured to receive power from the second HFAC power distribution bus.

The first HFAC power supply and the second HFAC power supply may be synchronised to provide HFAC power supplies which are in phase with each other. The electronic device may comprise a communication link between the first HFAC power supply and the second HFAC power supply for providing said synchronisation.

The first HFAC power supply and the second HFAC power supply may be configured to arbitrate via the communication link to assign one of a master status and a slave status to each power supply.

The power supplies may be configured so that, in the event that one power supply is disconnected, the remaining connected power supply is assigned master status. In examples, in the event that a power supply is reconnected it accepts slave status and synchronises its HFAC output with the HFAC power supply with master status.

In examples, the first HFAC power supply unit and the second HFAC power supply unit each provides HFAC with a constant frequency. For example, the frequency may be at least 900 kHz, for example at least 1 MHZ, for example between about 1 MHz and about 5 MHz, for example less than 3 MHZ, for example less than 2 MHz.

The first HFAC power distribution bus and the second HFAC power distribution bus may be connected to the component connection.

The electronic device may comprise two rectifiers for providing DC power to the component connection, wherein the first HFAC power distribution bus is connected to a first of the two rectifiers and the second HFAC power distribution bus is connected to a second of the two rectifiers.

The electronic device may comprise two DC-DC converters wherein each rectifier is connected to the component connection by a corresponding one of the two DC-DC converters.

The electronic device may comprise one DC-DC converter wherein both rectifiers are connected to the component connection by the DC-DC converter.

The electronic device may comprise an electronic component connected to the component connection. For example, the electronic component may be any of a processor, a network connector and a point of load converter.

An aspect of the disclosure is a server comprising a motherboard, wherein the motherboard comprises the features of the aforementioned motherboard.

An aspect of the disclosure provides a server comprising an electronic device according to another aspect of the disclosure. An aspect of the disclosure provides use of a server comprising an electronic device according to another aspect of the disclosure.

The HFAC distributions buses described herein may comprise multiple pairs of conduction paths, wherein each pair may comprise a live conduction path and a neutral conduction path. The pairs of conduction paths may be orientated parallel to one another on an electronic device and may have the same path length. for example wherein each of the pairs provides the same electrical path length from the power supply connection to the component connection as the other pairs. Each of the more than one pairs of electrical conduction paths may be matched with each other, for example wherein each pair of electrical conduction paths can be aligned with the other pairs, for example each pair of conduction paths can comprise elongate conductive members and may be disposed parallel to elongate conductive members of the other pairs.

The electronic devices may comprise one or more fail-safe circuits that disable the supply of power to the HFAC power distribution bus in the event of the failure or fault in a connected component and/or in the HFAC power distribution bus. This can prevent damage to connected components and/or the HFAC power distribution bus.

For example, the electronic device may comprise a logic circuit configured to selectively disable the first HFAC power supply in the event that a fault signal is provided to the logic circuit by a component connected to one of said component connections.

The logic circuit may be configured to disable the HFAC power supply in the event that the fault signal is provided by any one of a plurality of said components, for example by combining said fault signals using a logical OR. The component connected to one of said component connections may be carried by the first substrate.

The electronic device may comprise a logic circuit configured to selectively disable at least one of: (a) the first HFAC power supply and (b) the second HFAC power supply in the event that a fault signal is provided to the logic circuit by a component connected to one of said component connections.

In examples, one or more of the component connections may provide HFAC power to an electronic component configured to operate using HFAC power. For example, said electronic component may comprise AC circuitry designed to operate at high frequencies such as those outlined above. At least one of the HFAC power supplies may have a fixed voltage, which may be at least 10 V, for example at least 20V, for example between about 25V and 60V, for example less than 50V for example less than 45V.

The electronic devices described herein may comprise a multi-layer PCB, but other implementations are contemplated. For example, the structures described herein may be implemented in any substrate.

Any feature of any one of the examples disclosed herein may be combined with any selected features of any of the other examples described herein. For example, features of methods may be implemented in suitably configured hardware, and the configuration of the specific hardware described herein may be employed in methods implemented using other hardware.

### BRIEF DESCRIPTION OF THE DRAWINGS

Embodiments of the disclosure will now be described, by way of example only, with reference to the accompanying drawings, in which:

FIG. 1A illustrates a plan view of an electronic device;

FIG. 1B illustrates a cross-sectional view of the electronic device of FIG. 1A along the plane A-A;

FIG. 2A illustrates a plan view of a first layer of an electronic device;

FIG. 2B illustrates a plan view of a second layer of an electronic device;

FIG. 2C illustrates a cross-sectional view of the electronic device of FIGS. 2A and 2B along the plane C-C;

FIG. 3 illustrates a schematic view of a first HFAC-DC converter and a first DC electronic component;

FIG. 4 illustrates a schematic view of a second HFAC-DC converter and a second DC electronic component; and

FIG. 5 illustrates a plan view of a fail-safe logic circuit incorporated into the electronic device of FIG. 1A.

In the drawings like reference numerals indicate like elements.

### SPECIFIC DESCRIPTION

The present disclosure provides an electronic device with at least one embedded high frequency alternating current (HFAC) power distribution bus.

The following disclosure comprises:
A description of a first embodiment which is an electronic device which comprises a substrate, such as a layered structure comprising conductive layers and dielectric layers insulating the conductive layers from one another. One or more of the conductive layers provides an embedded HFAC power distribution bus for the supply of HFAC electrical power to components carried by the substrate. Electronic components can be mounted on the substrate and connected to the embedded HFAC power distribution bus. The layered structure comprises a ground plane or planes to shield part of the substrate from the components. The HFAC power distribution bus is provided in this shielded volume;
A description of a second embodiment which is an electronic device which provides redundancy in the HFAC power supply to electronic components mounted thereon. This is particularly suited for high reliability computing devices, such as servers and other electronic devices in which reliable operation is required. The electronic device of the second embodiment provides such reliability by redundancy (e.g. N+1 redundancy). In particular it comprises at least two HFAC power distribution buses wherein each of the HFAC power distribution buses has a connector for connecting each bus to a separate one of two respective separate HFAC power supplies. Each component powered by the busses may be connected to receive power from both buses. The two HFAC power supplies may be constant voltage power supplies, and they may be synchronised to provide HFAC of the same frequency, synchronised and in-phase with each other.
A first HFAC-DC converter for connecting a DC component to two HFAC power distribution buses;
A second HFAC-DC converter for connecting a DC component to two HFAC power distribution buses.
A fail-safe circuit for the described electronic devices that protects connected components in the event of a failure of or fault in a connected component or a HFAC distribution bus.

### First embodiment

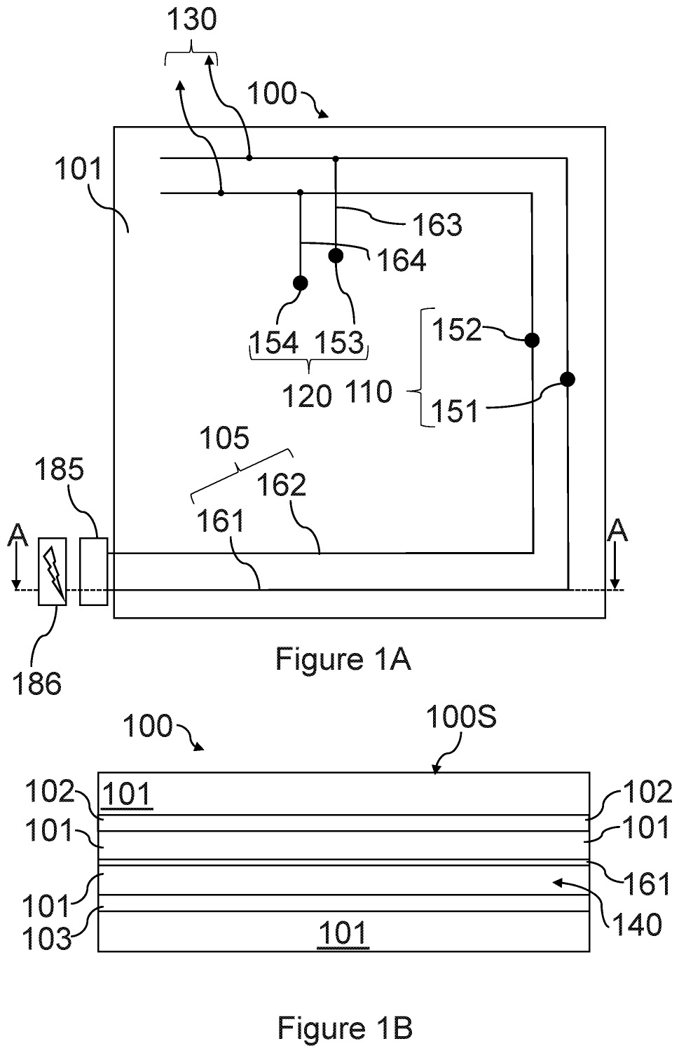

FIG. 1A illustrates a plan view of an electronic device 100 and FIG. 1B illustrates a cross-sectional view of the electronic device 100 of FIG. 1A along the plane A-A.

The electronic device 100 comprises: a first substrate 101; a first ground plane 102; a second ground plane 103; a first HFAC power distribution bus 105; a first component connection 110; a second component connection 120; a wired connection 130; a first power supply connection 185; and, a first HFAC power supply 186.

The electronic device 100 may be a circuit board, such as a multi-layer PCB. Such circuit boards may be suitable for use as motherboards for computing devices.

The first ground plane 102 and the second ground plane 103 are provided by layers disposed in the first substrate 101. The first substrate 101 is an insulator and each of the ground planes 102 and 103 is a conductor. The first ground plane 102 may be disposed parallel to the second ground plane 103, e.g., as separate layers of a multi-layered structure. The volume 140 between the first ground plane 102 and the second ground plane 103 is shielded by the two ground planes.

The first HFAC power distribution bus 105 is disposed in the shielded volume 140 between the first ground plane 102 and the second ground plane 103. The first power supply connection 185 is connected to the first HFAC power distribution bus 105. The first power supply connection 185 is configured for connecting the first HFAC power supply 186 to the HFAC power distribution bus.

A power supply 186 may be provided with the electronic device, e.g., connected to the supply connection 185. The power supply 186 and electronic device 100 may however be made and sold separately.

In FIG. 1a, the first power supply 186 is configured to provide HFAC power to the first power supply connection 185 at a constant frequency, for example the power supply may be configured to maintain constant frequency even when load on the bus varies. This may enable redundancy between power supplies in a manner not possible in variable frequency systems. Preferably the fixed frequency is selected from the range of 1 MHz to 2 MHZ (including the limits of said range).

In examples, the first power supply is configured to receive an AC power input and to provide an HFAC power output based on the AC power input. For example, the first power supply may be configured to receive an AC power input of 230 V (RMS) and a frequency of 50 Hz and provide an HFAC power output with a voltage within the range of 25 V to 45 V and a frequency within the range of 1 MHz to 2 MHz.

In examples, the first power supply is configured to receive a DC power input and to provide an HFAC power output based on the DC power input. For example, the first power supply may be configured to receive a DC power input of 400 V and provide an HFAC power output with a voltage within the range of 25 V to 45 V and a frequency within the range of 1 MHz to 2 MHz.

The first HFAC power distribution bus 105 comprises a pair of electrical conduction paths from the first power supply connection 185. The pair of electrical conduction paths may be provided by elongate conductive members which overly each other within the substrate.

The path length from each HFAC power supply connection to each component connection may be equal for the pair. In other words, the path length of the first path of the pair from the HFAC power supply to each component connection may be equal the path length of the second path of the pair from the HFAC power supply to that component connection. The two paths may be referred to herein as “live” 161 and a “neutral”. However, the two paths may be electrically equivalent in that the pair may simply be differentially driven by a transformer, e.g. the two are simply each side of an output transformer, there is no real live or neutral, they are interchangeable.

The live conduction path 161 and the neutral conduction path 162 are provided by conductive tracks in the substrate. The two paths may be laterally offset from each other as illustrated in FIG. 1A, however they may also be provided one atop the other—e.g., overlying one another embedded within the substrate, so that the two follow the same path but on different layers of the substrate. Other ways of providing equal conduction path length may be used.

As shown in FIG. 1A, the live conduction path 161 and the neutral conduction path 162 are each elongate conductive members disposed within the substrate 101. The elongate conductive members which form the live conduction path 161 and the neutral conduction path 162 are disposed parallel to each other. The live conduction path 161 is separated from the neutral conduction path 162 by part of the substrate 101 i.e. the region of the substrate 101 between the live conduction path and the neutral conduction path 162 shown in FIG. 1A.

Aligning the live conduction path 161 with the neutral conduction path 162 reduces the net H-field generated by the first HFAC power distribution bus compared to the same electronic device wherein the live conduction path 161 with the neutral conduction path 162 are not aligned.

The first component connection 110 permits connection of an electronic component to the first HFAC power distribution bus 105. The first component connection 110 comprises a first via 151 and a second via 152. The first via 151 and the second via 152 are a pair of channels disposed through the first ground plane 102 and the first substrate 101. The first via 151 permits electrical connection to the live conduction path 161 and the second via 152 permits electrical connection to the neutral conduction path 162.

The second component connection 120 permits connection of an electronic component to a conductive spur 170. The conductive spur 170 connects a component disposed at the second component connection 120 to the first HFAC power distribution bus 105.

The conductive spur 170 comprises a pair of conductive traces. The pair of conductive traces comprises a first conductive trace 163 connected to the live conduction path 161 and a second conductive trace 164 connected to the neutral conduction path 162. The second component connection 120 comprises a third via 153 and a fourth via 154. The third via 153 and the fourth via 154 are a pair of channels disposed through the first ground plane 102 and the first substrate 101. The third via 153 permits connection to the live conduction path 161 through the first conductive trace 163 and the fourth via 154 permits connection to the neutral conduction path 162 through the second conductive trace 164.

Electronic components disposed at any of the first component connection 110 and the second component connection 120 may be carried on the first substrate 101 e.g., the electronic components may be disposed on the surface 101S of the first substrate 101 (such as “surface mount” components. The electronic components may comprise terminals which connected to the bus 105 by vias into the shielded volume.

DC electronic components are connected to the first HFAC power distribution bus 105 via an HFAC-DC conversion circuit (not shown in FIGS. 1A and 1B). The HFAC-DC conversion circuit comprises an input for receiving HFAC power and an output for providing DC power (e.g. smoothed DC power) based on the HFAC power. The HFAC-DC conversion circuit can be any of: carried at the component connections on the electronic device 100; provided as a component which is separate from the electronic device 100 and the electronic component at the component connection; and, provided as an integral part of the DC component (e.g. as a driver).

The HFAC-DC conversion circuit comprises a rectifier, a resonant converter and a filter. HFAC passes through the rectifier to provide a primary DC voltage. The primary DC voltage is converted to a secondary DC voltage by the resonant converter. The secondary DC voltage is smoothed by the filter to provide a smoothed DC voltage. The terminals of DC electronic components receive the smoothed DC voltage (i.e. which extend through the vias and contact an output of the HFAC-DC conversion circuit).

The live conduction path 161 to the first component connection 110 is the same length as the neutral conduction path 162 to the first component connection 110. In use, the net H-field generated by the first HFAC power distribution is first HFAC power distribution bus 105 is comparatively reduced compared to the same electronic device wherein the live conduction path 161 with the neutral conduction path 162 are not of equal length. Similarly the live conductive path to the second component location (i.e. the sum of the lengths of the first conductive trace 163 and the portion of the live conduction path 161 thereto) is equal to the neutral conductive path to the second component location (i.e. the sum of the lengths of the second conductive trace 164 and the portion of the neutral conduction path 162 thereto). Similarly the live conductive path to the second substrate is equal to the neutral conductive path to the second substrate.

The wired connection 130 permits electrical connection of a second substrate (not shown in FIGS. 1A and 1B). The second substrate may be similar to the first substrate 101. The second substrate has a pair of ground planes arranged to provide a shielded volume in the second substrate. The second substrate comprises an HFAC power distribution bus which is connected to the first HFAC power distribution bus 105 by the wired connection 130. For example, the second substrate may be a daughterboard. In examples, the second substrate is a fan PCB or a fan tray.

The first HFAC power distribution bus 105 may have more than one pair of electrical conduction paths. The additional pairs of electrical conduction paths can be implemented in the same way as the first conduction paths described above.

Conduction of high frequency current can lead to a physical phenomenon known as the skin effect in which the current density within the conductor becomes largest at the surface of a conductor. This can cause an increase in the resistance of the conductor, which is disadvantageous to power transmission and can also result in damage to the areas of the conductor that experience a high current density. Additional pairs of electrical conduction paths can be used to address the problem caused by the skin effect that can occur in electrical conductors when conducting high frequency alternating current.

The additional pairs of electrical conduction paths distribute the power from the HFAC power supply between the pairs of electrical conduction paths thereby reducing the total power transmitted through a single pair of electrical conduction paths. This reduces the current density in any one single pair of electrical conductions paths and can mitigate the problems associated with the skin effect described above.

The live and neutral conduction paths (for example 161 and 162) of the one or more pairs of electrical conduction paths associated with the first HFAC power distribution bus 105 can collectively form a first live conduction path and a first neutral conduction path to which a component connection 110, 120 can be made. These collectively formed first live conduction path and first neutral conduction path effectively function as the first live conduction path 161 and the first neutral path 162 described above with reference to FIG. 1.

In embodiments in which the first HFAC power distribution bus 105 has more than one pair of electrical conduction paths, connection of components to the first HFAC power distribution bus can be implemented in a similar way to the example first HFAC power distribution bus 105 described above.

In one example, the first component connection 110 permits connection of an electronic component to the first HFAC power distribution bus 105. The first component connection 110 comprises a first via 151 and a second via 152. The first via 151 and the second via 152 are a pair of channels disposed through the first ground plane 102 and the first substrate 101. The first via 151 permits electrical connection to the live conduction path collectively formed from the live conduction paths of each of the pairs of electrical conduction paths and the second via 152 permits electrical connection to the neutral conduction path collectively formed from the neutral conduction paths of each of the pairs of electrical conduction paths. The second component connection 120 permits connection of an electronic component to a conductive spur 170. The conductive spur 170 connects a component disposed at the second component connection 120 to the first HFAC power distribution bus 105.

Multiple pairs of electrical conduction paths can be arranged in a parallel orientation so as to reduce the net H-field generated by the HFAC power distribution bus and it is also advantageous for the path length of each pair of electrical conduction paths to be the same.

For example, wherein each pair of conduction paths comprises elongate conductive members disposed parallel to elongate conductive members of the other pairs.

In examples, one or more of the component connections may provide HFAC power to an electronic component configured to operate using HFAC power. It will be appreciated in the context of the present disclosure that HFAC power supply may comprise a power supply frequency having a frequency of 1 MHz or more, and generally less than 10 MHZ, for example less than 5 MHZ, preferably less than 2 MHz. The electronic component may also comprise AC circuitry designed to operate at high frequencies e.g. at least 900 kHz, for example 1 MHz to 2 MHz.

In use, the first HFAC power distribution bus 105 receives HFAC power from the first power supply connection 185. A potential difference is provided between the live conduction path 161 and the neutral conduction path 162. A component connected to both the live conduction path 161 and the neutral conduction path 162 derives power from the first HFAC power distribution bus 105 i.e. a high frequency alternating current flows from the live conduction path 161, through the HFAC-DC converter at the component connection, the (smoothed) DC power powers the electronic component.

### Second Embodiment

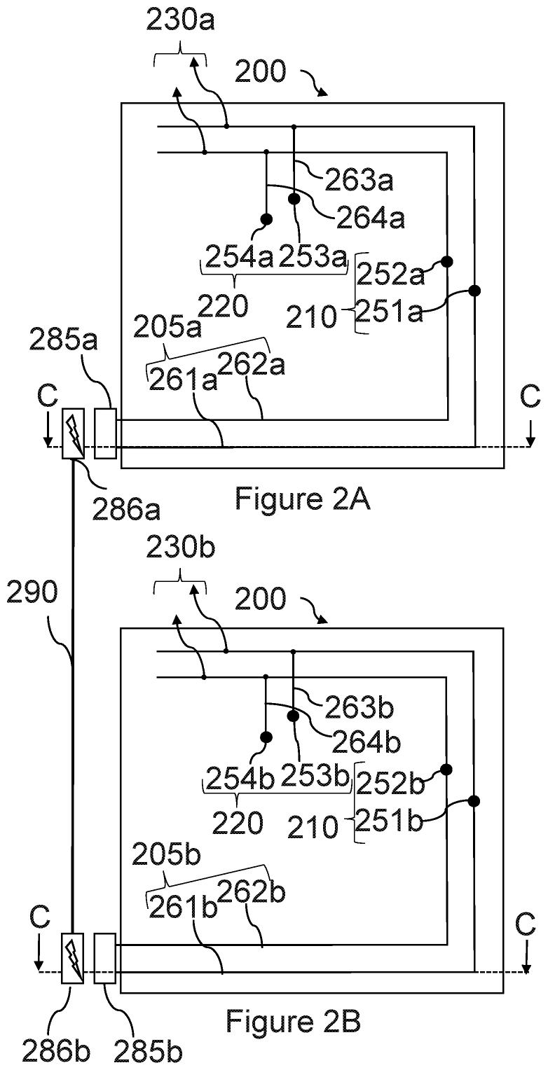

FIG. 2A illustrates a plan view of a first layer of an electronic device 200, FIG. 2B illustrates a plan view of a second layer of the electronic device 200, and FIG. 2C illustrates a cross-sectional view of the electronic device 200 of FIGS. 2A and 2B along the plane C-C.

The electronic device 200 comprises: a first substrate 201; a first ground plane 202; a second ground plane 203; a first HFAC power distribution bus 205a; a second HFAC power distribution bus 205b; a first component connection 210; a second component connection 220; a wired connection 230; a first power supply connection 285a; a first HFAC power supply 286a; a second power supply connection 285b; and, a second HFAC power supply 286b.

In the present example, the electronic device 200 is a circuit board. In such examples, the circuit board may be used as a motherboard in a server.

The first ground plane 202 and the second ground plane 203 are disposed within the first substrate 201. The first substrate 201 is an insulator and each of the ground planes 202 and 203 is a conductor. The first ground plane 202 is disposed parallel to the second ground plane 203 to provide a shielded volume 240 between the two ground planes.

The first HFAC power distribution bus 205a is disposed in the shielded volume 240 i.e. the first HFAC power distribution bus 205a is disposed within the first substrate 201 between the first ground plane 202 and the second ground plane 203. The second HFAC power distribution bus 205b is disposed in the shielded volume 240. The first power supply connection 285a is connected to the first HFAC power distribution bus 205a. The first power supply connection 285a is configured for connecting the first HFAC power supply 286a to the first HFAC power distribution bus 205a. The second power supply connection 285b is connected to the second HFAC power distribution bus 205b and is configured to connect the second HFAC power supply 286b to the second HFAC power distribution bus 205b.

FIG. 2A illustrates the first power supply 286a and the second power supply 286b as part of the electronic device 200, however, in examples, an electronic device may be provided with a first power supply connection and a second power supply connection only i.e. the electronic device may be sold or otherwise provided without the first and second power supplies. The first power supply 286a and the second power supply are configured to provide HFAC power to the first power supply connection 285a and the second power supply connection 285b respectively at a constant frequency i.e. the frequency of the HFAC power provided by the first power supply 286a does not change in use (e.g. in response to a given load). Similarly, the frequency of the HFAC power provided by the second power supply 286a does not change in use. Preferably the fixed frequency is selected from the range of 1 MHz to 2 MHZ (including the limits of said range).

In examples, at least one of the first and second power supplies is configured to receive an AC power input and to provide an HFAC power output based on the AC power input. For example, the first power supply may be configured to receive an AC power input of 230 V (RMS) and a frequency of 50 Hz and provide an HFAC power output with a voltage within the range of 25 V to 45 V and a frequency within the range of 1 MHz to 2 MHZ.

In examples, at least one of the first and second power supplies is configured to receive a DC power input and to provide an HFAC power output based on the DC power input. For example, the second power supply may be configured to receive a DC power input of 400 V and provide an HFAC power output with a voltage within the range of 25 V to 45 V and a frequency within the range of 1 MHz to 2 MHz.

The first HFAC power distribution bus 205a comprises a pair of electrical conduction paths from the first power supply connection 285a. The pair of electrical conduction paths are referred to herein as a first live conduction path 261a and a first neutral conduction path 262a, but as outlined above it will be appreciated that neither may be referenced to ground and both may float and simply provide a differential voltage signal. The two paths of each power distribution bus may be laterally offset from each other as illustrated in FIG. 2A, however they may also be provided one atop the other—e.g., overlying one another embedded within the substrate, so that the two follow the same path but on different layers of the substrate

The second HFAC power distribution bus 205b is identical to the first HFAC power distribution bus 205a, but spaced apart from it in the substrate. The second HFAC power distribution bus 205b comprises like elements indicated by like reference numerals e.g. the second live conduction path 261b and the second neutral conduction path 262b.

In examples, the first neutral conduction path 261a and the second neutral conduction path 261b can be connected to a reference voltage other than ground.

The first live conduction path 261a and the first neutral conduction path 262a are spatially aligned with each other. As shown in FIG. 1A, the first live conduction path 261a and the first neutral conduction path 162a are each elongate conductive members disposed within the first substrate 201. The elongate conductive members which form the first live conduction path 261a and the first neutral conduction path 262a are disposed parallel to each other. The first live conduction path 261 is separated from the first neutral conduction path 262 by part of the first substrate 201 i.e. the region of the first substrate 201 between the first live conduction path 261a and the first neutral conduction path 262b shown in FIG. 2A.

The second live conductive path 261b and the second neutral conduction path 262b identical to the first live and neutral conduction paths e.g. the second live conductive path 261b and the second neutral conduction path 262b are spatially aligned with each other et cetera. The first live conduction path 261a and the first neutral conduction path 262a are separated from the second live conductive path 261b and the second neutral conduction path 262b respectively by part of the first substrate 201 as shown in FIG. 2C.

Aligning the first live conduction path 261a with the first neutral conduction path 262a reduces the net H-field generated by the first HFAC power distribution bus compared to the same electronic device wherein the first live conduction path 261a with the first neutral conduction path 262 are not aligned. The same effect is also achieved by aligning the second live conduction path 261b with the second neutral conduction path 262b.

The first HFAC power distribution bus 205a and the second HFAC power distribution bus 205b each have a planar shape. The first HFAC power distribution bus 205a and the second HFAC power distribution bus 205b are arranged parallel to one another and with identical orientations i.e. so that the like elements in each bus are disposed adjacent one another. For example, the first power supply connection 285a is arranged adjacent the second power supply connection 285b and the first conductive elements that the first conductive trace 263a of the first HFAC power distribution bus 205a is disposed adjacent the first conductive trace 263b of the second HFAC power distribution bus 205b et cetera.

FIG. 2C illustrates a cross-sectional view of the electronic device 200. The first live conduction path 261a is parallel to and arranged above the second live conduction path 261b. Although not shown in FIG. 2C, the first neutral conduction path 262a is parallel to and arranged above the second neutral conduction path 262b.

The first component connection 210 permits connection of an electronic component to the first HFAC power distribution bus 205a and to the second HFAC power distribution bus 205b. The first component connection 210 comprises a first via 251a and a second via 252a, a third via 251b and a fourth via 252b. The first via 251a and the second via 252a are a pair of channels disposed through the first ground plane 202, the first substrate 201. The first via 251a permits electrical connection to the first live conduction path 261a of the first HFAC power distribution bus 205a. The second via 252a permits electrical connection to the first neutral conduction path 262a of the first HFAC power distribution bus 205a. The third via 251b and the fourth via 252b are a pair of channels disposed through the first ground plane 202, the first substrate 201 and the first HFAC power distribution bus 205a. The third via 251b permits electrical connection to the second live conduction path 261b of the second HFAC power distribution bus 205b. The fourth via 252b permits electrical connection to the second neutral conduction path 262b of the second HFAC power distribution bus 205b.

The first via 251a and second via 252a are offset from the third via 251b and the fourth via 252b i.e. the first via 251a is not disposed atop the third via or fourth via 251b and 252b and the second via 252a is not disposed atop the third via or fourth via 251b and 252b.

The second component connection 220 permits connection of an electronic component to a first conductive spur 270a and a second conductive spur 270b. The first conductive spur 270a connects a component disposed at the second component connection 220 to the first HFAC power distribution bus 205a. The second conductive spur 270b connects a component disposed at the second component connection 220 to the second HFAC power distribution bus 205b.

The first conductive spur 270a comprises a first pair of conductive traces. The first pair of conductive traces comprises a first conductive trace 163a connected to the first live conduction path 261a and a second conductive trace 164a connected to the first neutral conduction path 262a. Similarly, the second conductive spur 270b comprises a second pair of conductive traces. The second pair of conductive traces comprises a first conductive trace 263b connected to the second live conduction path 261b and a second conductive trace 264b connected to the second neutral conduction path 162b.

The second component connection 220 comprises a first via 253a and a second via 254a, a third via 253b and a fourth via 254b.

The first via 253a and the second via 254a are a pair of channels disposed through the first ground plane 202, the first substrate 201. The first via 253a permits electrical connection to the first conductive trace 263a of the first conductive spur 270a which is connected to the first live conduction path 261a of the first HFAC power distribution bus 205a. The second via 254a permits electrical connection to the second conductive trace 263b of the first conductive spur 270a which is connected to the first neutral conduction path 262a of the first HFAC power distribution bus 205a.

The third via 253b and the fourth via 254b are a pair of channels disposed through the first ground plane 202, the first substrate 201 and the first HFAC power distribution bus 205a. The third via 253b permits electrical connection to the first conductive trace 263b of the second conductive spur 270b which is connected to the second live conduction path 261b of the second HFAC power distribution bus 205b. The fourth via 254b permits electrical connection to the second conductive trace 264b of the second conductive spur 270b which is connected to the second neutral conduction path 262b of the second HFAC power distribution bus 205b.

The first via 253a and second via 254a are offset from the third via 253b and the fourth via 254b i.e. the first via 253a is not disposed atop the third via or fourth via 253b and 254b and the second via 254a is not disposed atop the third via or fourth via 253b and 254b.

Electronic components disposed at any of the first component connection 210 and the second component connection 220 are carried on the first substrate 201 e.g. the electronic components are disposed on the surface 201S of the first substrate 201. The electronic components comprise terminals which extend through the vias to electrically connect the electronic components to the first HFAC power distribution bus 205a and the second HFAC power distribution bus 205b.

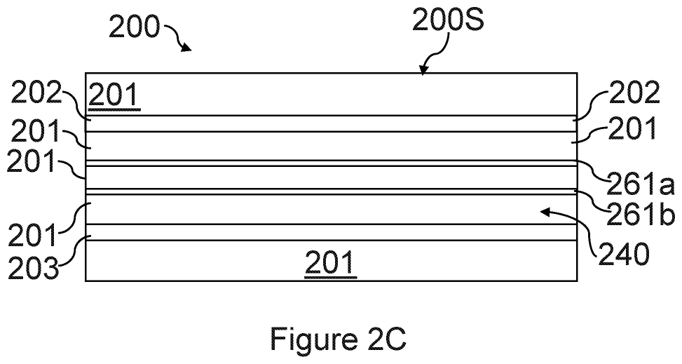

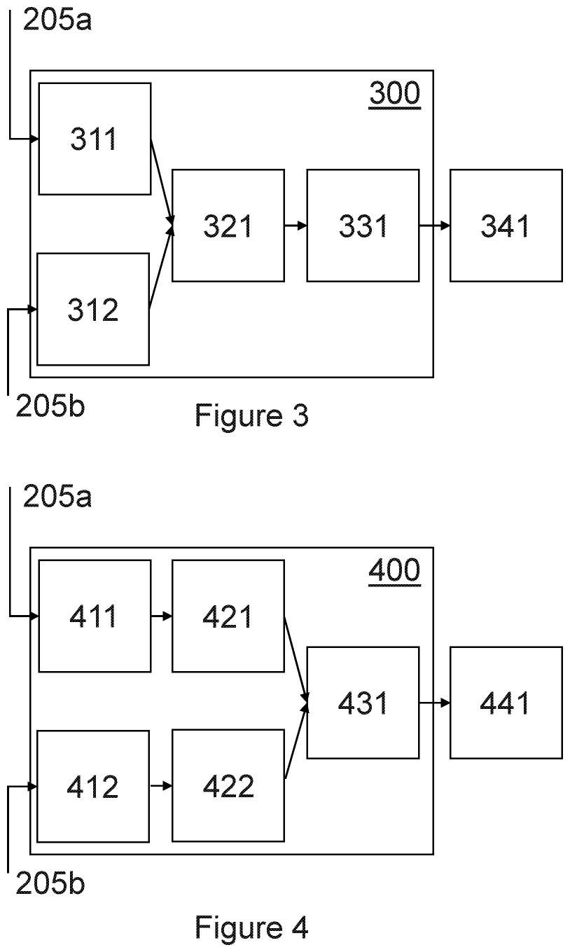

DC electronic components are connected to the first HFAC power distribution bus 205a and the second HFAC power distribution bus via an HFAC-DC conversion circuit. Two examples of HFAC-DC conversion circuits are illustrated in FIGS. 3 and 4 and described in more detail herein. The HFAC-DC conversion circuit can be any of: carried at the component connections on the electronic device 200; provided as a component which is separate from the electronic device 200 and the electronic component at the component connection; and, provided as an integral part of the DC component (e.g. as a driver).

The first live conduction path 261a to the first component connection 210 is the same length as the first neutral conduction path 262a to the first component connection 210. In use, the net H-field generated by first HFAC power distribution bus 205a is comparatively reduced compared to the same electronic device wherein the first live conduction path with the first neutral conduction path are not of equal length. Similarly, the first live conductive path to the second component location is equal to the first neutral conductive path to the second component location. Similarly, the second live and neutral conduction paths to each component location have the same lengths to likewise reduce the net H-field generated in use.

The wired connection 230 permits electrical connection of a second substrate (not shown in the Figures). The second substrate may be similar to the first substrate 201. The second substrate has a pair of ground planes arranged to provide a shielded volume in the second substrate. The second substrate comprises a third HFAC power distribution bus which is connected to the first HFAC power distribution bus 205a by the first wired connection 230a. The second substrate comprises a fourth HFAC power distribution bus which is connected to the second HFAC power distribution bus 205b by the second wired connection 230b. For example, the second substrate may be a daughterboard. In examples, the second substrate is a fan PCB or a fan tray.

The communication link 290 permits synchronisation the HFAC output of the first power supply 286A and the HFAC output of the second power supply 286B e.g. so that the output HFAC of the first power supply 286A is in phase with the output HFAC of the second power supply 286B. The power supplies may be synchronised as outlined above. The first HFAC power supply and the second HFAC power supply are configured to arbitrate via the communication link 290 to assign one of a master status and a slave status to each power supply.

The first power supply 286A and the second power supply 286B are configured so that, in the event that one power supply is disconnected, the remaining connected power supply is assigned master status.

For example, if the first power supply 286A is assigned master status and the second power supply 286B is assigned slave status, then in the event that the first power supply 286A is disconnected, the second power supply 286B is assigned master status (i.e. the status of the second power supply 286B changes from slave to master). If subsequently the first power supply 286A is reconnected, the first HFAC power supply 286A and the second HFAC power supply 286B arbitrate via the communication link 290. In this instance, as the second HFAC power supply 286B has master status and, therefore, said arbitration results in the first HFAC power supply 286A being assigned slave status. The first HFAC power supply 286A, being assigned slave status, synchronises its HFAC output with the second HFAC power supply 286B which has the master status.

In use, the first power supply 286a delivers HFAC power to the first HFAC power distribution bus 205a and the second power supply 286b delivers HFAC power to the second HFAC power distribution bus 205b. The first and second power supplies arbitrate through the communication link 290 to synchronise their respective HFAC outputs and to assign a master status to one of the supplies and a slave status to another. The first HFAC power distribution bus 205a receives HFAC power from the first power supply connection 285a and the second HFAC power distribution bus 205b receives HFAC power from the second power supply connection 285b. A first potential difference is provided between the first live conduction path 261a and the first neutral conduction path 262a and a second potential difference is provided between the second live conduction path 261b and the second neutral conduction path 262b.

A component connected to both the first live conduction path 261a and the neutral conduction path 262 derives power from one of the HFAC power distribution buses i.e. the bus connected to the power supply assigned master status. The HFAC-DC converter at the component connection, converts the HFAC power to (smoothed) DC power. The DC power is used to power the electronic component.

The first and second HFAC power distribution buses 205a and 205b may have more than one pair of electrical conduction paths from the first and second power supply connections respectively. The additional pairs of electrical conduction paths can be implemented in the same way as the first and second pairs of electrical conduction paths, 261a,262a and 262b, 262b described herein in reference to FIGS. 2A and 2B.

Additional pairs of electrical conduction paths can be used to address the problem caused by skin effect that can occur in electrical conductors when conducting high frequency alternating current.

The additional pairs of electrical conduction paths distribute the power supply received by the more than one pair of electrical conduction paths from each of the power supply connections, 286a and 286b, thereby reducing the total power transmitted through a single pair of electrical conduction paths this reduces the current density in any one single pair and can mitigate the problems associated with the skin effect described above.

The live and neutral conduction paths of the one or more pairs of electrical conduction paths of the first HFAC distribution bus 205a can collectively form a first live conduction path and a first neutral conduction path (one example of a live and a neutral conduction path of a pair of electrical conduction paths being 261a, 262a). The collective live and neutral conduction paths of the one or more pairs of electrical conduction paths of the first HFAC power distribution bus 205a function as live and neutral conduction paths 261a and 262a.

The live and neutral conduction paths of the one or more pairs of electrical conduction paths of the second HFAC power distribution bus 205b can collectively form a second live conduction path and a second neutral conduction path (one example of a live and neutral conduction path of a pair of electrical conduction paths being 261b,262b). The collective live and neutral conduction paths of the one or more pairs of electrical conduction paths of the second HFAC power distribution bus 205b function as live and neutral conduction paths 261b and 262b.

In embodiments in which the first and second HFAC power distribution buses 205a and 205b each have more than one pair of electrical conduction paths component connections to the first and second HFAC power distribution buses 205a,205b can be implemented in a similar way to the example first and second HFAC power distribution buses 205a, 205b described above in reference to FIGS. 2A and 2B.

In one example, a first component connection 210 permits connection of an electronic component to the first HFAC power distribution bus 205a and to the second HFAC power distribution bus 205b. The first component connection 210 comprises a first via 251a and a second via 252a, a third via 251b and a fourth via 252b. The first via 251a and the second via 252a are a pair of channels disposed through the first ground plane 202, the first substrate 201. The first via 251a permits electrical connection to the first live conduction path of the first HFAC power distribution bus 105, the first live conduction path comprising the live conduction paths of all of the one or more pairs of electrical conduction paths associated with the first HFAC power distribution bus 205a. The second via 252a permits electrical connection to the first neutral conduction path of the first HFAC power distribution bus 205a, the first neutral conduction path comprising the neutral conduction paths of all of the one or more pairs of electrical conduction path associated with the first HFAC distribution bus 205a. The third via 252a and the fourth via 252b are a pair of channels disposed through the first ground plane 202, the first substrate 201 and the first HFAC power distribution bus 205a. The third via 252a permits electrical connection to the second live conduction path of the second HFAC power distribution bus 205b the second live conduction path comprising the neutral conduction paths of all of the one or more pairs of electrical conduction path associated with the second HFAC power distribution bus 205b. The fourth via 252b permits electrical connection to the second neutral conduction path of the second HFAC power distribution bus 205b the second neutral conduction path comprising the neutral conduction paths of all of the one or more pairs of electrical conduction path associated with the second HFAC power distribution bus 205b.

The multiple pairs of electrical conduction paths can be arranged in a parallel orientation so as to reduce the net H-field generated by the HFAC power distribution bus and it is also advantageous for the path length of each pair of electrical conduction paths to be the same. For example, wherein each pair of conduction paths comprises elongate conductive members disposed parallel to elongate conductive members of the other pairs.

### Component Connection 1

FIG. 3 illustrates a schematic view of a first HFAC-DC converter 300 for providing power to a first DC component 341 at a component connection. The first HFAC-DC converter is disposed between the first HFAC power distribution bus 205a and the second HFAC power distribution bus 205b. The first HFAC-DC converter rectifies the HFAC power to DC and also provides N+1 redundancy to the first DC component 341 connected.

The first HFAC-DC converter 300 comprises: a first rectifier 311; a second rectifier 312; a first DC to DC (DC-DC) converter 321; a first filter 331.

An input of the first rectifier 311 is connected to the first HFAC power distribution bus 205a. An output of the first rectifier 311 is connected to the first DC-DC converter 321. The first rectifier 311 receives, through its input, HFAC power from the first HFAC power distribution bus 205a. The first rectifier 311 converts the input HFAC power to an output DC power. The first rectifier 311 provides, through its output, DC power to the first DC-DC converter 321.

In a similar manner, an input of the second rectifier 312 is connected to the second HFAC power distribution bus 205b. An output of the second rectifier 312 is connected to the first DC-DC converter 321. The second rectifier 312 receives, through its input, HFAC power from the second HFAC power distribution bus 205b. The second rectifier 312 converts the input HFAC power to an output DC power. The second rectifier 312 provides, through its output, DC power to the first DC-DC converter 321. In embodiments where two separate rectifiers are provided for each DC-DC converter, one for each HFAC bus, then the power supplies from the HFAC buses need not be in-phase at the rectifier inputs. It may be advantageous to ensure equal voltage on the two buses and/or at the two rectifier outputs. Appropriate circuitry may be provided to achieve this.

The first rectifier 311 and/or the second rectifier 312 may each comprise synchronous rectifiers (e.g. active rectifiers) but passive rectifiers may also be used.

An input of the first DC-DC converter 321 is connected to the first rectifier 311 and the second rectifier 312. The first DC-DC converter 321 is connected to receive DC power from both the first rectifier 311 and the second rectifier 312. Thus, in the event that the first rectifier 311 fails to provide DC power, the first DC-DC converter 322 can simply draw power from the second rectifier 312.

An output of the first DC-DC converter 321 is connected to the first filter 331. The first DC-DC converter 321 is configured to provide an output of DC power with a second voltage, based on the first voltage i.e. the first DC-DC converter 321 changes the first DC voltage to the second DC voltage.

An input of the first filter 331 is connected to the first DC-DC converter 321. The first filter 331 is configured to receive DC power having the second voltage. The first filter 331 is configured to smooth the received DC power to thereby provide a smoothed DC voltage.

An output of the first filter 331 is connected to the first DC component 341. The first filter 331 provides the smoothed DC voltage to the first DC component 341.

An input of the first DC component 341 is connected to the first filter 331. The first DC component 341 receives the smoothed DC voltage from the first filter 331. The first DC component 341 is configured to provide a function of the electronic device e.g. a processing function.

### Component Connection 2

FIG. 4 illustrates a schematic view of a second HFAC-DC converter 400 for providing power to a second DC component 441 at a component connection. The second HFAC-DC converter 400 is disposed between the first HFAC power distribution bus 205a and the second HFAC power distribution bus 205b. The second HFAC-DC converter 400 rectifies the HFAC power to DC and also provides N+1 redundancy to the second DC component 441 connected.

The second HFAC-DC converter 400 comprises: a first rectifier 411; a second rectifier 412; a first DC to DC (DC-DC) converter 421; a second DC-DC converter 422; a first filter 431.

An input of the first rectifier 411 is connected to the first HFAC power distribution bus 205a. An output of the first rectifier 411 is connected to the first DC-DC converter 421. The first rectifier 411 receives, through its input, HFAC power from the first HFAC power distribution bus 205a. The first rectifier 411 converts the input HFAC power to an output DC power. The first rectifier 411 provides, through its output, DC power to the first DC-DC converter 421.

An input of the second rectifier 412 is connected to the second HFAC power distribution bus 205b. An output of the second rectifier 412 is connected to the second DC-DC converter 422. The second rectifier 412 receives, through its input, HFAC power from the second HFAC power distribution bus 205b. The second rectifier 412 converts the input HFAC power to an output DC power. The second rectifier 412 provides, through its output, DC power to the second DC-DC converter 422.

The first rectifier 411 and/or the second rectifier 412 may comprise a synchronous rectifier.

An input of the first DC-DC converter 421 is connected to the first rectifier 411. The first DC-DC converter 421 is configured to receive DC power with a primary voltage from the first rectifier 411. An output of the first DC-DC converter 421 is connected to the first filter 431. The first DC-DC converter 421 is configured to provide an output of DC power with a secondary voltage, based on the primary voltage i.e. the first DC-DC converter 421 changes the primary DC voltage to the secondary DC voltage.

Similarly, an input of the second DC-DC converter 422 is connected to the second rectifier 411. The first DC-DC converter 421 is configured to receive DC power with a primary voltage from the second rectifier 412. An output of the second DC-DC converter 422 is connected to the first filter 431. The second DC-DC converter 422 is configured to provide an output of DC power with a secondary voltage, based on the primary voltage i.e. the second DC-DC converter 422 changes the primary DC voltage to the secondary DC voltage.

An input of the first filter 431 is connected to the first DC-DC converter 421 and the second DC-DC converter 422. The first filter 431 is configured to receive DC power having the second voltage from either the first DC-DC converter 421 and the second DC-DC converter 422. In use, the first filter 431 is configured to receive DC power from both the first DC-DC converter 421 and the second DC-DC converter 422.

The first filter 431 is configured to smooth the received DC power to thereby provide a smoothed DC voltage. An output of the first filter 431 is connected to the second DC component 441. The first filter 431 provides the smoothed DC voltage to the second DC component 441.

An input of the second DC component 441 is connected to the first filter 431. The second DC component 441 receives the smoothed DC voltage from the first filter 431. The first DC component 441 is configured to provide a function of the electronic device e.g. a processing function.

### Current Limit Safety Circuit

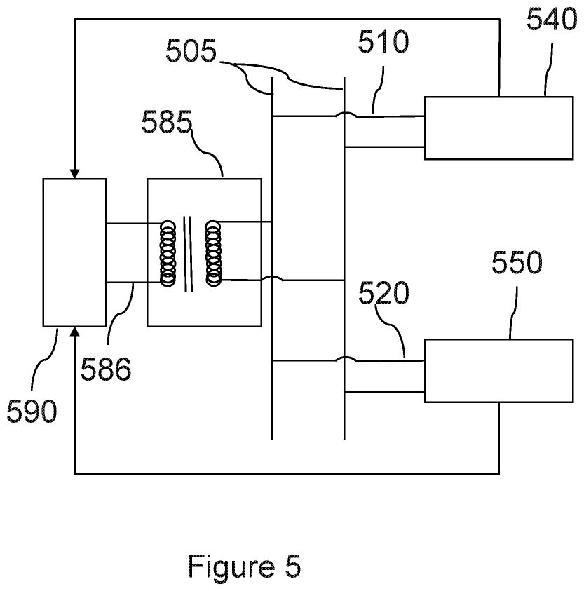

FIG. 5 illustrates an example of a current limit circuit 590 that may be deployed in the electronic devices 100,200 described herein to improve their response to fault conditions. It will be appreciated that this arrangement may be deployed in any of the apparatus described and/or claimed herein such as that described with reference to FIG. 1, and FIGS. 2A and 2B.

The apparatus 500 illustrated in FIG. 5 comprises an HFAC distribution bus 505 such as the HFAC distribution buses 105, 205a, 205b described above. The apparatus further comprises component connections 510 and 520 such as the component connections 110 and 120 described above.

The apparatus 500 comprises an HFAC power supply 586 such as any one or more of the HFAC power supplies 186, 286a, 286a described above. It further comprises an HFAC power supply connection 585 such as any one or more of the HFAC power supply connections 185, 285a, 285b described above. In this example the HFAC power supply connection 585 may comprise a transformer which couples the HFAC power supply 586 to the HFAC distribution bus 505.

In the example shown in FIG. 5, components 540 and 550 are connected to the HFAC power distribution bus 505 via component connections 510 and 520. The component 540 may comprise a first voltage supply, powered by the HFAC, for supplying a first voltage level to other components of the device. The component 550 may comprise a second voltage supply, also powered by the HFAC, for supplying a second voltage level, which is different from the first voltage level to other components of the device. For example the first voltage level may be 5 volts and the second voltage level may be 12 volts. Other voltage levels and additional components may also be provided.

The components 540, 550, are connected to a logic circuit 590, which is operable selectively to enable and disable the HFAC power supply 586, for example by switching off an inverter of the power supply. For example the logic circuit 590 may be configured to operate a disconnector to disconnect a DC power supply from the inverter. Other methods of disabling the inverter may also be used.

The components 540, 550 are both configured to provide a fault signal to the logic circuit 590 in the event of a fault condition, such as the component 540, 550 exceeding a current limit.

The logic circuit 590 is configured to disable the HFAC power supply 586 in the event that either of the components 540, 550, provides a fault signal to the logic circuit.

In operation, the HFAC power distribution bus 505 receives HFAC power from the HFAC power supply 586 via the HFAC power supply connection 585.

In the event that either of the components 540, 550 draws more than a predetermined level of current, the component which has exceeded the limit provides a fault signal to the logic circuit 590. The logic circuit 590 then cuts power to the HFAC power distribution bus by turning off HFAC power supply 586. This may be done by stopping the inverter, disconnecting it from DC power and/or by isolating the HFAC power supply 586 from the HFAC power distribution bus 505.

It will be appreciated in the context of the present disclosure that in addition to overcurrent faults, the components 540, 550, may be configured to detect many other types of fault. Such fault conditions may be detected by any of the means which will be apparent to the skilled addressee in the context of the present disclosure. For example the fault may be detected by a change in apparent resistance in the components or a change in voltage across a sense resistor. The logic circuit may monitor at least one of: power; root mean square current (RMS) current; and Peak current in the connected components so as to detect faults. The connected components may for example provide a fault signal to the logic circuit 590 based on at least one of: power; root mean square current (RMS) current; and Peak current. Other types of fault detection may be used.

In the example shown in FIG. 5 the apparatus may provide a fail-safe circuit between the component connections 510, 520 and the HFAC power supply 586. Other arrangements of the fail-safe circuit 590 are envisaged for example the fail-safe circuit 590 may connect to the connected components 540,550 directly and/or directly to the HFAC power supply connection 585.

The fail-safe circuit 590 ensures that power is cut to the HFAC power distribution bus 505 in the event of the failure or fault in any one of the components connected to component connections 510 and 520 and/or in the HFAC power distribution bus 505. This can prevent damage to connected components and/or the HFAC power distribution bus 505.

Further embodiments are envisaged. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

In examples of any of the preceding embodiments, a first HFAC power distribution bus is connected to a first power supply connection and a second power supply connection. Therefore, the first HFAC power distribution bus can receive power from a first and a second power supply connected to the respective power supply connections. In such examples, the first HFAC power distribution bus and the second HFAC power distribution bus are synchronised.

Embodiments of the disclosure may comprise standard mains AC connectors for providing a power source to the HFAC power supplies. The output from the HFAC power supplies may use an industry standard power connector or a PCB blade type connector.

Where ranges are recited herein these are to be understood as disclosures of the limits of said range and any intermediate values between the two limits.

With reference to the drawings in general, it will be appreciated that schematic functional block diagrams are used to indicate functionality of systems and apparatus described herein. It will be appreciated however that the functionality need not be divided in this way, and should not be taken to imply any particular structure of hardware other than that described and claimed below. The function of one or more of the elements shown in the drawings may be further subdivided, and/or distributed throughout apparatus of the disclosure. In some embodiments the function of one or more elements shown in the drawings may be integrated into a single functional unit.

The above embodiments are to be understood as illustrative examples. Further embodiments are envisaged. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

These claims are to be interpreted with due regard for equivalents.

1. An electronic device comprising:
a first substrate comprising a first ground plane and a second ground plane, wherein the first ground plane and the second ground plane are arranged to provide a shielded volume there between;
a first high frequency alternating current (HFAC) power distribution bus disposed in the shielded volume, wherein the first HFAC power distribution bus is configured for connecting to a first HFAC power supply;
a first power supply connection for connecting the first HFAC power supply to the first HFAC power distribution bus;
a component connection for connecting the first HFAC power distribution bus to electronic components carried by the first substrate.

2. The electronic device of claim 1 wherein the first HFAC power distribution bus comprises a pair of electrical conduction paths from the power supply connection to the component connection.

3. The electronic device of claim 2 wherein the pair of electrical conduction paths are a matched pair, for example wherein they provide the same electrical path length from the power supply connection to the component connection, for example wherein the pair of electrical conduction paths are aligned with each other, for example wherein they comprise elongate conductive members disposed parallel to each other.

4. The electronic device of claim 3 comprising an HFAC power supply connected to the power supply connection, wherein the power supplies are configured such that H-field generated by the first HFAC power distribution bus is reduced by the matching of the pair of electrical conduction paths, for example by their being aligned with each other.

5. The electronic device of claim 2, 3, or 4, wherein the pair of electrical conduction paths are separated by part of the first substrate, for example wherein the pair of electrical conduction paths overlie each other on different layers of the substrate.

6. The electronic device of claim 2, 3, or 4, wherein the pair of electrical conduction paths are separated by part of the first substrate are laterally separated from each other for example wherein they are spaced apart on the same layer of the substrate.

7. The electronic device of any of claims 2 to 5 comprising a plurality of first conductive spurs connected between the first HFAC power distribution bus and corresponding ones of a plurality of component connections.

8. The electronic device of claim 7 wherein said conductive spurs comprise a pair of conductive traces.

9. The electronic device of any of claims 7 to 8 wherein the component connections are provided by vias through the first ground plane or the second ground plane.

10. The electronic device of any of claims 7 to 9 wherein at least one of the component connections connects the first HFAC power distribution bus to an electronic component disposed outside of the shielded volume.

11. The electronic device of any of the preceding claims comprising a second power supply connection for connecting an HFAC power supply to the HFAC power distribution bus.

12. The electronic device of claim 11 comprising a synchronisation connection for connecting HFAC power supplies connected to the power supply connections to enable the HFAC power supplies to synchronise with each other.

13. The electronic device of any of claims 11 to 12 comprising a second HFAC power distribution bus disposed in the shielded volume, for example wherein the second HFAC power distribution bus is configured for connecting to the second HFAC power supply.

14. The electronic device of claim 13, wherein the first HFAC power distribution bus and the second HFAC power distribution bus is connected to the component connection.

15. The electronic device of claim 14, comprising two rectifiers for providing DC power to the component connection, wherein the first HFAC power distribution bus is connected to a first of the two rectifiers and the second HFAC power distribution bus is connected to a second of the two rectifiers.

16. The electronic device of claim 15, comprising two DC-DC converters wherein each rectifier is connected to the component connection by a corresponding one of the two DC-DC converters.

17. The electronic device of claim 15, comprising one DC-DC converter wherein both rectifiers are connected to the component connection by the DC-DC converter.

18. The electronic device of any of the preceding claims, comprising a wired connection for connecting the first HFAC power distribution bus to a second substrate separate from the first substrate.

19. The electronic device of claim 18 comprising the second substrate, wherein the wired connection connects to a third HFAC power distribution bus in the second substrate.

20. The electronic device of any of claims 2 to 19, comprising more than one pair of electrical conduction paths from the power supply connection to the component connection.

21. The electronic device of claim 20 wherein each of the more than one pairs of electrical conduction paths are matched with each other, for example wherein each pair of electrical conduction paths are aligned with the other pairs, for example wherein each pair of conduction paths comprises elongate conductive members disposed parallel to elongate conductive members of the other pairs.

22. The electronic device of claim 20 or 21 wherein the more than one pairs of electrical conduction paths have the same path length, for example wherein each of the pairs provides the same electrical path length from the power supply connection to the component connection as the other pairs.

23. An electronic device comprising:
a first HFAC power distribution bus,
a first HFAC power supply connected to the first HFAC power distribution bus;
a second HFAC power distribution bus,
a second HFAC power supply connected to the second HFAC power distribution bus;
at least one component connection for connecting an electronic component to be powered to the first HFAC power distribution bus and the second HFAC power distribution bus.

24. The electronic device of claim 23, wherein the first HFAC power supply and the second HFAC power supply are synchronised to provide HFAC power supplies which are in phase with each other.

25. The electronic device of claim 24, comprising a communication link between the first HFAC power supply and the second HFAC power supply for providing said synchronisation.

26. The electronic device of claim 25, wherein the first HFAC power supply and the second HFAC power supply are configured to arbitrate via the communication link to assign one of a master status and a slave status to each power supply

27. The electronic device of claim 26 wherein the power supplies are configured so that, in the event that one power supply is disconnected, the remaining connected power supply is assigned master status.

28. The electronic device of claim 27 wherein in the event that a power supply is reconnected it accepts slave status and synchronises its HFAC output with the HFAC power supply with master status.

29. The electronic device of any of claims 24 to 28 wherein the first HFAC power supply unit and the second HFAC power supply unit each provides HFAC with a constant frequency, for example at least 900 kHz for example in the range of 1 MHz to 2 MHz.

30. The electronic device of any of claims 23 to 28, wherein the first HFAC power distribution bus and the second HFAC power distribution bus is connected to the component connection, for example by a rectifier.

31. The electronic device of claim 30, comprising two rectifiers for providing DC power to the component connection, wherein the first HFAC power distribution bus is connected to a first of the two rectifiers and the second HFAC power distribution bus is connected to a second of the two rectifiers.

32. The electronic device of claim 31, comprising two DC-DC converters for each component connection wherein each rectifier is connected to the each component connection by a corresponding one of the two DC-DC converters.

33. The electronic device of claim 31, comprising one DC-DC converter for each component connection wherein both rectifiers are connected to the component connection by the one DC-DC converter.

34. The electronic device of any of the preceding claims comprising an electronic component connected to the component connection.

35. The electronic device of any of claims 1 to 34, the device comprising a logic circuit configured to selectively disable the first HFAC power supply in the event that a fault signal is provided to the logic circuit by a component connected to one of said component connections.

36. The electronic device of claim 35 wherein the logic circuit is configured to disable the HFAC power supply in the event that the fault signal is provided by any one of a plurality of said components, for example by combining said fault signals using a logical OR.

37. The electronic device of claim 35 or 36 wherein the component connected to one of said component connections is carried by the first substrate.

38. The electronic device of any of claims 23 to 34 preceding claim comprising a logic circuit configured to selectively disable at least one of:
(a) the first HFAC power supply and
(b) the second HFAC power supply
in the event that a fault signal is provided to the logic circuit by a component connected to one of said component connections.
